(19) United States
(12) Patent Application Publication
(10) Pub. No.: US 2010/0144084 A1
(43) Pub. Date: Jun. 10, 2010

(54) OPTICAL WAVEGUIDE STRUCTURES FOR AN IMAGE SENSOR

(76) Inventors: Hung Q. Doan, Rochester, NY (US); Joseph R. Summa, Hilton, NY (US)

Correspondence Address: Pedro P. Hernandez;Patent Legal Staff, Eastman Kodak Company, 343 State Street, Rochester, NY, 14650-2201, US

(21) Appl. No.: 12/328,796

(22) Filed: Dec. 5, 2008

(51) Int. Cl. H01L 31/18

(52) U.S. Cl. 438/72; 257/E31.127

(57) ABSTRACT

Trenches that are filled with a reflecting material are formed in one or more dielectric layers in an image sensor. The trenches form optical waveguide structures that surround either partially or completely each photodetector in the image sensor. Each optical waveguide structure directs light towards a respective photodetector.

### TECHNICAL FIELD

The present invention relates generally to image sensors for use in digital cameras and other types of image capture devices, and more particularly to methods of forming optical waveguide structures in image sensors.

### BACKGROUND

Charge Coupled Device (CCD) and Complementary Metal Oxide Semiconductor (CMOS) image sensors are commonly used in digital imaging systems such as digital still cameras, video cameras, and scanners. CCD image sensors typically serve markets that require superior image quality, while CMOS image sensors usually serve markets that require high system integration and lower cost. CCD and CMOS image sensors include pixels having photodetectors that generate charge carriers in response to light striking the pixels.

One concern with image sensors is crosstalk. Crosstalk is a phenomenon where the charge carriers generated in one pixel are actually collected in another pixel. Crosstalk degrades the performance of an image sensor by causing lower quantum efficiency, higher noise levels, color mixing, and hue shifts. Crosstalk is usually classified into two types, optical crosstalk and electrical crosstalk. Electrical crosstalk occurs when generated carriers generated at one pixel location in the semiconductor substrate diffuse or migrate laterally and are collected by an adjacent pixel. Optical crosstalk refers to the scattering of light as the light transverses an optical path.

Light can travel any one of a number of optical paths once it enters the image sensor. If light strikes a pixel at normal incidence (perpendicular to the photodetector), the light will strike the photodetector contained within that pixel. But if light strikes a pixel at a non-perpendicular angle, the optical path of the light can lead the light into an adjacent pixel. This is why optical crosstalk can occur more often at the edge of an array of pixels because light enters these regions at shallow angles.

A number of approaches have been proposed to reduce optical crosstalk. The most common proposal is to form optical paths with materials having differing indexes of reflection or refraction. When light strikes a boundary between a higher index material and a lower index material, the light tends to reflect back into the higher index material. If the angle at which the light strikes the boundary is kept below a critical angle, then a total internal reflection occurs. One example of this technique is the formation of air gaps around a pixel area. Air gap guard rings were proposed in an article by Dun-Nian Yaung entitled “Air Gap Guard Ring for Pixel Air Gap Guard Ring for Pixel Sensitivity and Crosstalk Improvement in Deep Submicron CMOS Image Sensor,” PROC. OF IEDM (2003).

Unfortunately, the air gap guard rings can have potential reliability problems. The expansion or collapse of trapped moisture in each air gap during temperature cycling, either from packaging or device operation, can induce film cracking and other problems.

U.S. Pat. No. 6,696,899 discloses another technique for forming optical paths with materials having different indexes of reflection or refraction. Different dielectric materials having different indexes of refraction are used to form optical paths. One dielectric layer having a high index of refraction fills the light guides and another conformal dielectric layer having a lower refractive index is disposed on the inside walls of the light guides. When light strikes the interface between the two dielectric layers, some or all of the light is reflected back into the third dielectric layer.

This technique, however, requires additional masking and extra processing steps when forming the light guides. It also relies on materials having different indexes of refraction. Thus, the angle of entry of the light must be below a critical angle for total internal reflection to occur. The bigger the index difference between the two materials, the higher the critical angle, but it is difficult to find a suitable dielectric or other material that has a smaller index of refraction than that of standard silicon dioxide.

### SUMMARY

A method for fabricating optical waveguides in an image sensor, where the image sensor includes a substrate having a plurality of photodetectors formed therein that form an imaging area. One or more dielectric layers are formed over the imaging area. For example, the dielectric layers can include an inter-level-dielectric (ILD) layer or an inter-metal-dielectric (IMD) layer. Trenches are then etched into each dielectric layer as the layers are formed in one embodiment in accordance with the invention. The trenches can be etched into each dielectric layer at the same time as the vias. In another embodiment in accordance with the invention, the trenches are etched after two or more dielectric layers are formed.

The trenches can be formed by forming a mask layer over the imaging area and patterning the mask layer to form openings in the mask layer that correspond to the locations of the trenches. The dielectric layer is etched through the openings in the mask layer to form the trenches in at least a portion of one dielectric layer. In another embodiment in accordance with the invention, two or more dielectric layers are etched to form trenches in multiple dielectric layers at the same time. The mask layer is then removed.

The trenches are then filled or partially filled with a reflecting material. The reflecting material can include, for example, a metal film or a combination of metal films. The trenches are filled at the same time as the vias in one embodiment in accordance with the invention. Subsets of the trenches are disposed around the edges of each pixel or photodetector and form optical waveguide structures. Each optical waveguide structure directs light towards a respective photodetector. The trenches can be formed such that each optical waveguide has straight or substantially straight sidewalls, or each level of trenches can be laterally shifted or eased with respect to an underlying set of trenches.

### BRIEF DESCRIPTION OF THE DRAWINGS

FIG. 1 is a simplified block diagram of an image capture device in an embodiment in accordance with the invention;

FIGS. 2-10 are simplified cross section views illustrating a method for fabricating optical waveguides in an image sensor in an embodiment in accordance with the invention;

FIG. 11 is a simplified cross section view depicting an alternate fabrication step to the step shown in FIG. 2 in an embodiment in accordance with the invention;

FIG. 12 is a simplified cross section view depicting a first alternate fabrication step to the step shown in FIG. 4 in an embodiment in accordance with the invention;

FIG. 13 is a simplified cross section view illustrating an alternate fabrication step to the step shown in FIG. 4 in an embodiment in accordance with the invention;

FIG. 14 is a simplified cross section view of a first alternate image sensor to the image sensor 200 shown in FIG. 10 in an embodiment in accordance with the invention

FIG. 15 is a simplified cross section view illustrating a second alternate image sensor to the image sensor 200 shown in FIG. 10 in an embodiment in accordance with the invention;

FIG. 16 is a top view of an image sensor in a first embodiment in accordance with the invention; and

FIG. 17 is a top view of an image sensor in a second embodiment in accordance with the invention.

### DETAILED DESCRIPTION

Throughout the specification and claims the following terms take the meanings explicitly associated herein, unless the context clearly dictates otherwise. The meaning of “a,” “an,” and “the” includes plural reference, the meaning of “in” includes “in” and “on.” The term “connected” means either a direct electrical connection between the items connected or an indirect connection through one or more passive or active intermediary devices. The term “circuit” means either a single component or a multiplicity of components, either active or passive, that are connected together to provide a desired function. The term “signal” means at least one current, voltage, or data signal.

Additionally, directional terms such as “on”, “over”, “top”, “bottom”, are used with reference to the orientation of the Figure(s) being described. Because components of embodiments of the present invention can be positioned in a number of different orientations, the directional terminology is used for purposes of illustration only and is in no way limiting. When used in conjunction with layers of an image sensor wafer or corresponding image sensor, the directional terminology is intended to be construed broadly, and therefore should not be interpreted to preclude the presence of one or more intervening layers or other intervening image sensor features or elements. Thus, a given layer that is described herein as being formed on or formed over another layer may be separated from the latter layer by one or more additional layers.

And finally, the terms “wafer” and “substrate” are to be understood as a semiconductor-based material including, but not limited to, silicon, silicon-on-insulator (SOI) technology, doped and undoped semiconductors, epitaxial layers formed on a semiconductor substrate, and other semiconductor structures.

Referring to the drawings, like numbers indicate like parts throughout the views.

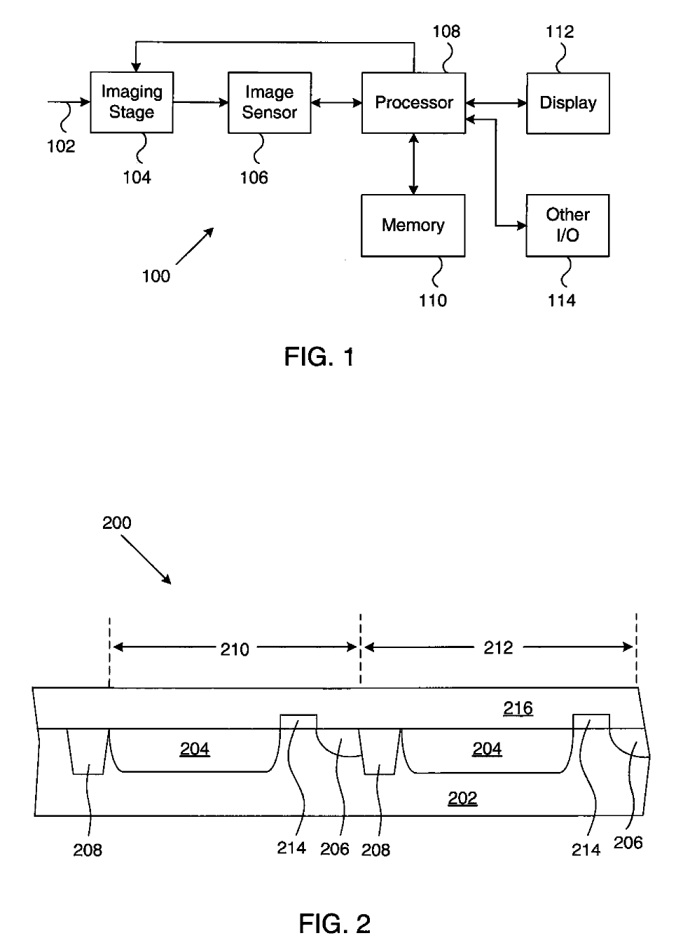

FIG. 1 is a simplified block diagram of an image capture device in an embodiment in accordance with the invention. Image capture device 100 is implemented as a digital camera in FIG. 1. Those skilled in the art will recognize that a digital camera is only one example of an image capture device that can utilize an image sensor incorporating the present invention. Other types of image capture devices, such as, for example, cell phone cameras and digital video camcorders, can be used with the present invention.

In digital camera 100, light 102 from a subject scene is input to an imaging stage 104. Imaging stage 104 can include conventional elements such as a lens, a neutral density filter, an iris and a shutter. Light 102 is focused by imaging stage 104 to form an image on image sensor 106. Image sensor 106 captures one or more images by converting the incident light into electrical signals. As will be described in more detail herein, optical waveguides are formed around each pixel or photodetector in image sensor 106.

Digital camera 100 further includes processor 108, memory 110, display 112, and one or more additional input/output (I/O) elements 114. Although shown as separate elements in the embodiment of FIG. 1, imaging stage 104 may be integrated with image sensor 106, and possibly one or more additional elements of digital camera 100, to form a camera module. For example, a processor or a memory may be integrated with image sensor 106 in a camera module in embodiments in accordance with the invention.

Processor 108 may be implemented, for example, as a microprocessor, a central processing unit (CPU), an application-specific integrated circuit (ASIC), a digital signal processor (DSP), or other processing device, or combinations of multiple such devices. Various elements of imaging stage 104 and image sensor 106 may be controlled by timing signals or other signals supplied from processor 108.

Memory 110 may be configured as any type of memory, such as, for example, random access memory (RAM), read-only memory (ROM), Flash memory, disk-based memory, removable memory, or other types of storage elements, in any combination. A given image captured by image sensor 106 may be stored by processor 108 in memory 110 and presented on display 112. Display 112 is typically an active matrix color liquid crystal display (LCD), although other types of displays may be used. The additional I/O elements 114 may include, for example, various on-screen controls, buttons or other user interfaces, network interfaces, or memory card interfaces.

It is to be appreciated that the digital camera shown in FIG. 1 may comprise additional or alternative elements of a type known to those skilled in the art. Elements not specifically shown or described herein may be selected from those known in the art. As noted previously, the present invention may be implemented in a wide variety of image capture devices. Also, certain aspects of the embodiments described herein may be implemented at least in part in the form of software executed by one or more processing elements of an image capture device. Such software can be implemented in a straightforward manner given the teachings provided herein, as will be appreciated by those skilled in the art.

FIGS. 2-10 are simplified cross section views illustrating a method for fabricating optical waveguides in an image sensor in an embodiment in accordance with the invention. For the sake of simplicity, FIGS. 2-10 depict only two pixels in an image sensor. Those skilled in the art will recognize that an image sensor typically includes a large number of pixels. For example, an image sensor can include millions of pixels.

FIG. 2 shows a portion of an image sensor 200 at the completion of a number of initial steps of an exemplary CMOS fabrication process. Image sensor 200 at this stage includes substrate 202, photodetectors 204, charge-to-voltage conversion mechanisms 206, shallow trench isolation (STI) regions 208 that isolate adjacent pixels from one anther (e.g., pixels 210, 212), transfer gates 214, and Inter-Level-Dielectric (ILD) layer 216.

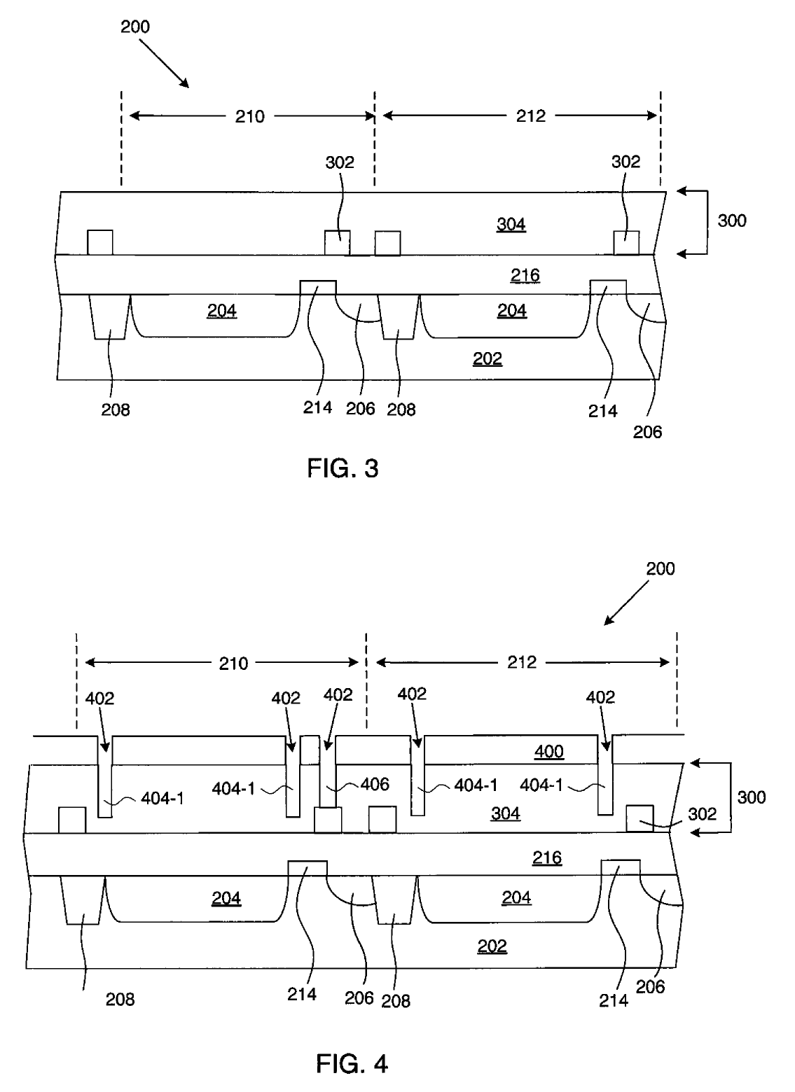

After the formation of contacts (not shown) to different elements shown in FIG. 2, such as, for example, contacts to charge-to-voltage conversion mechanisms 206 or to transfer gates 214, an Inter-Metal-Dielectric (IMD) layer 300 is formed over ILD layer 216 (see FIG. 3). IMD layer 300 includes conductive interconnects 302 and dielectric layer 304. IMD layer 300 is formed by first depositing a conductive film over ILD layer 216 and then patterning and etching the conductive film to form conductive interconnects 302. Dielectric layer 304 is then formed over conductive interconnects 302 and ILD layer 216. In one embodiment in accordance with the invention, dielectric layer 304 is formed by depositing a dielectric material over the image sensor 200 and etching a portion of it back so that the top surface of dielectric layer 304 is flat. By way of example only, a Chemical-Mechanical-Polishing (CMP) technique or plasma etch can be used to etch dielectric layer 304.

Conductive interconnects 302 are implemented as metal interconnects in an embodiment in accordance with the invention. In other embodiments in accordance with the invention, conductive interconnects 302 are formed using in-laid or a damascene technique, similar to the process used to form copper lines. Dielectric layer 304 isolates conductive interconnects 302 from each other and from additional conductive interconnects yet to be formed.

Referring now to FIG. 4, a mask layer 400, such as a photoresist, is deposited and patterned to create openings 402. Trenches 404-1 and vias 406 (contacts between conductive interconnects) are then simultaneously formed in dielectric layer 304 in an embodiment in accordance with the invention. Forming the trenches and vias at the same time eliminates the need for additional processing steps. For example, openings 402 for both trenches 404-1 and vias 406 are formed at the same time in dielectric layer 304, thereby eliminating the need to use one mask layer for the formation of vias 406 and another mask layer for the formation of trenches 404-1. As will be described in more detail below, trenches 404-1 form a first trench level in two yet-to-be completed optical waveguide structures. As such, the trenches in the first trench level are identified with the reference number 404-1.

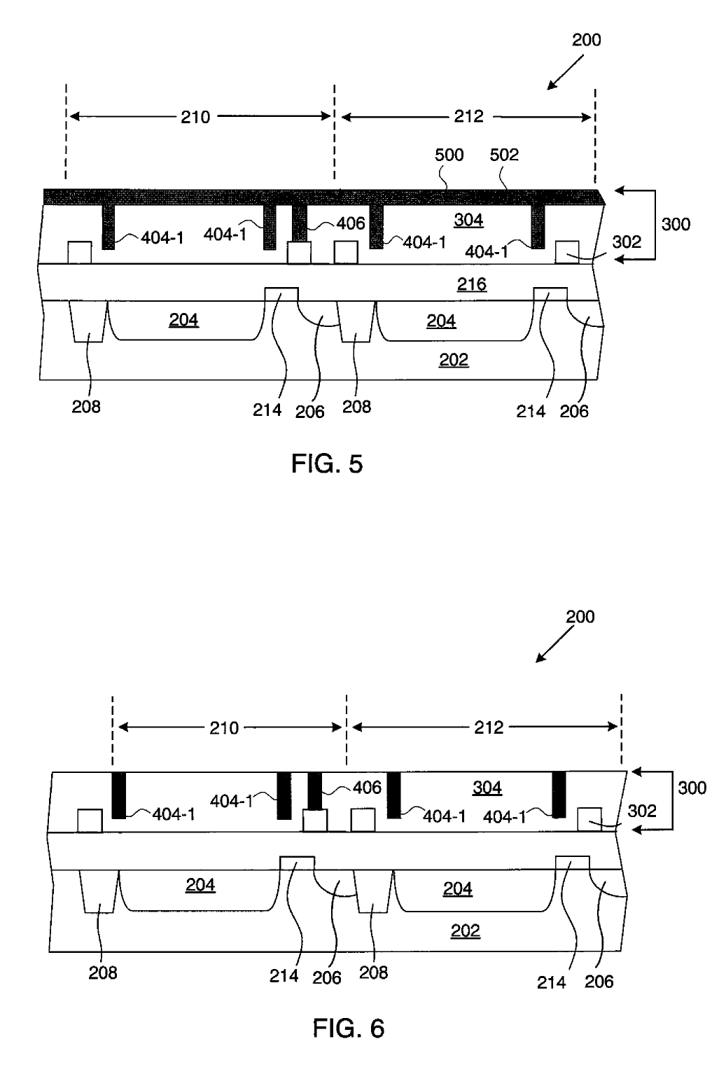

Mask layer 400 is then removed and a reflecting material 500 formed over image sensor 200 (see FIG. 5). The reflecting material fills trenches 404-1 and vias 406, and is disposed on a top surface 502 of IMD layer 300. Another advantage to the present invention is that trenches 404-1 are filled with reflecting material 500 at the same time as vias 406. No additional processing steps are needed to fill the trenches 404-1.

In the embodiment shown in FIG. 5, reflecting material 500 is implemented as a metal film or a combination of metal films. One example of a metal film that can be used is tungsten (W). Examples of metal film combinations include, but arc not limited to, titanium nitride (TiN) and tungsten (W). Tungsten (W) and copper (Cu), or tungsten (W), nitrogen (N), tantalum (Ta), tantalum nitride (TaN), tungsten nitride (WN) and copper (Cu), are other common combinations of metal films that can be used to fill trenches 404-1 and vias 406.

The reflecting material 500 is then removed from surface 502. The reflecting material 500 is etched or polished off using a CMP process in an embodiment in accordance with the invention. Reflecting material 500 fills trenches 404-1 and vias 406 after the reflecting material is removed from surface 502. FIG. 6 depicts image sensor 200 after the reflecting material 500 has been removed from the surface of IMD layer 300.

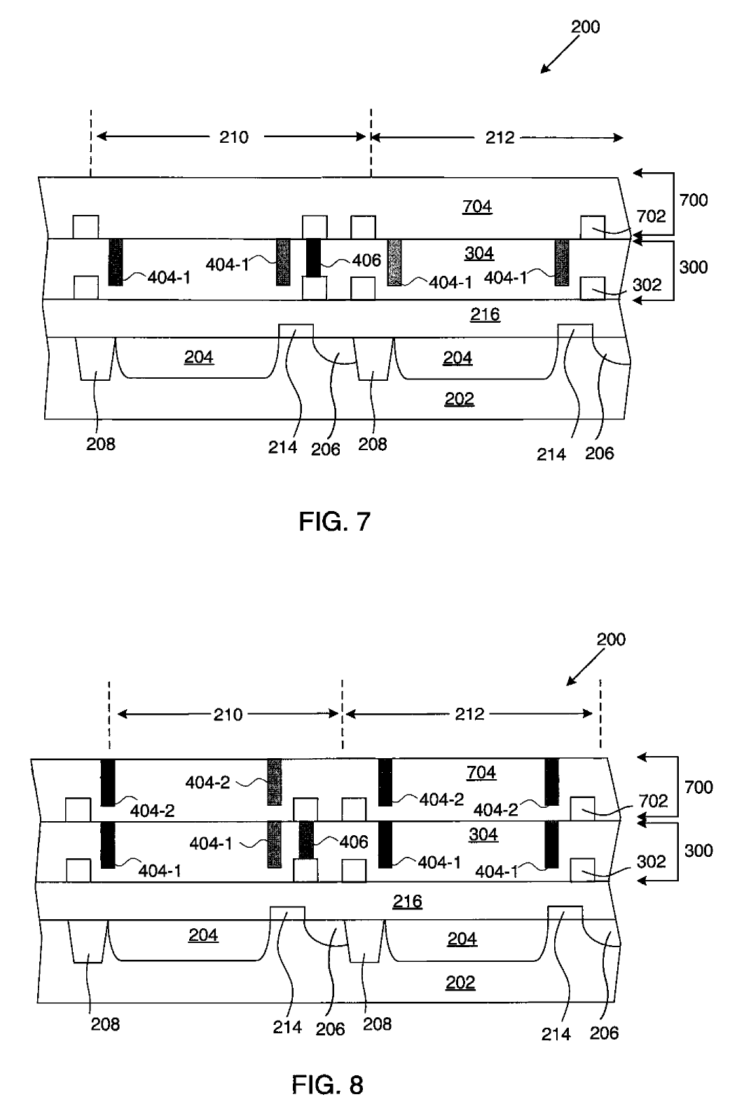

Referring now to FIG. 7, a second IMD layer 700 is formed on the surface of IMD layer 300. IMD layer 700 includes conductive interconnects 702 and dielectric layer 704. The process used to form IMD layer 700 is the same process used to for IMD layer 300 (see FIG. 3).

A second trench level of the optical waveguides is then formed in dielectric layer 704. The process used to form trenches 404-2 is the same process used to form trenches 404-1 (see FIGS. 4 and 5). A mask layer (not shown) is deposited and patterned to create openings where trenches 404-2 are to be formed. Trenches 404-2 are then formed in dielectric layer 704 and the mask layer removed. A reflecting material (not shown) is formed over IMD layer 700. The reflecting material fills trenches 404-2 and is disposed on the surface of IMD layer 700. The reflecting material is then removed from the surface of IMD layer 700, leaving the reflecting material in trenches 404-2. FIG. 8 depicts image sensor 200 at this stage of the fabrication process.

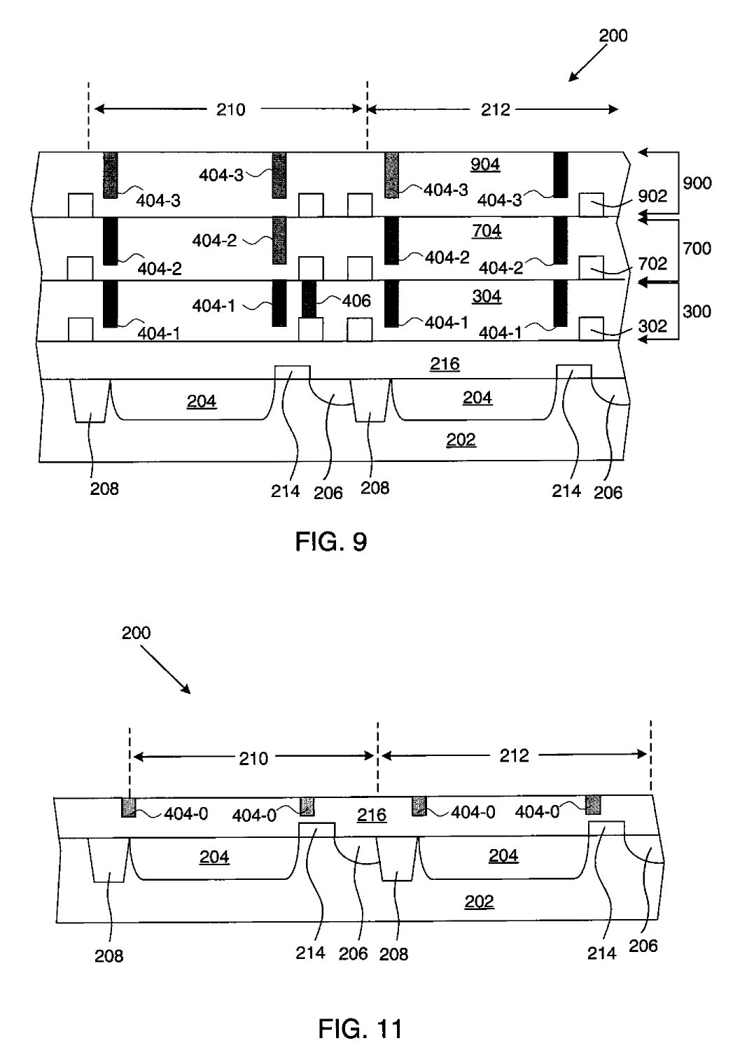

Referring now to FIG. 9, a third ND layer 900 that includes conductive interconnects 902 and dielectric layer 904, and a third trench level of the optical waveguides, are then formed on image sensor 200. The process used to form IMD layer 900 is the same process used to form IMD layer 700. The process used to form trenches 404-3 is the same process used to form trenches 404-1 (see FIGS. 4 and 5) and trenches 404-2.

Although FIG. 9 depicts three IMD layers 300, 700, 900 with each layer including a trench level of the optical waveguides formed therein, other embodiments in accordance with the invention are not limited to the same number of IMD layers or trench levels. Forming additional IMD layers and additional trench levels of the optical waveguides can be repeated as many times as desired. Similarly, less than three IMD layers or trench levels can be used in an image sensor.

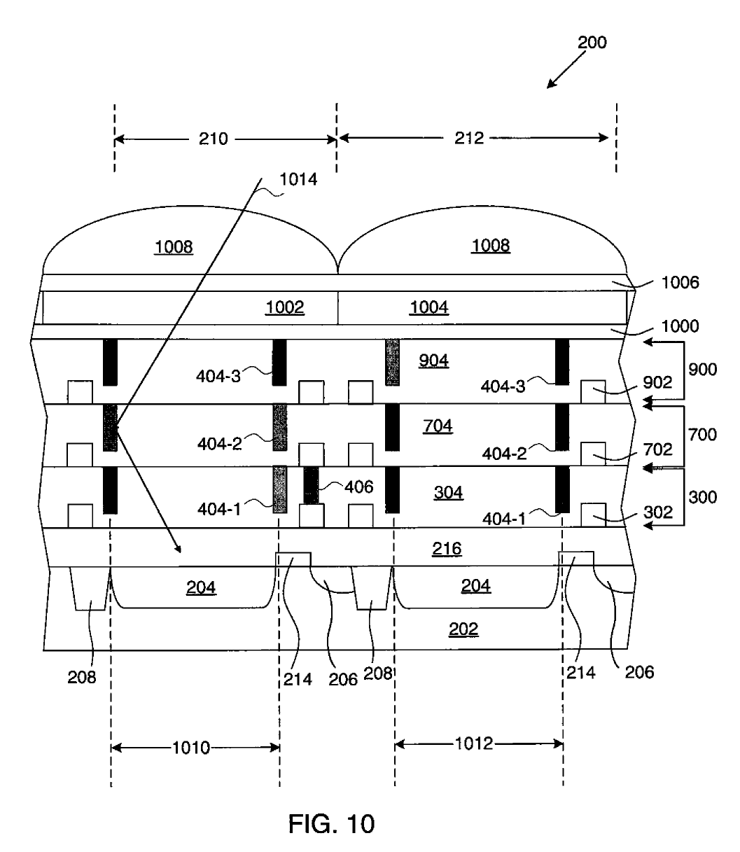

Once all of the desired IMD layers and trench levels of the optical waveguide structures have been formed, a passivation layer 1000 is formed on the top surface of IMD layer 900 (see FIG. 10). Color filters 1002, 1004 are then formed on the top surface of passivation layer 1000. Color filters 1002, 1004 act as bandpass filters in that each filter passes a select range of wavelengths of light and blocks all other wavelengths. By way of example only, color filter 1002 can pass light propagating a wavelengths associated with the color red, while color filter 1004 can pass light propagating a wavelengths associated with the color green.

Planar layer 1006 is formed on the top surfaces of color filters 1002, 1004. Planar layer 1006 is used to form a flat surface on image sensor 200. Microlenses 1008 are then formed on the top surface of planar layer 1006. Other embodiments in accordance with the invention can fabricate pixels 110, 112 with different elements or without some of the elements shown in FIGS. 2-10. By way of example only, pixels in other embodiments in accordance with the invention are fabricated without charge-to-voltage converter 206.

Together trenches 404-1, 404-2, 404-3 form optical waveguide structures 1010, 1012. When light 1014 strikes a pixel at an angle (e.g., pixel 210), optical waveguide structure 1010 directs the light 1014 towards photodetector 204. Optical waveguide structures 1010, 1012 reduce or prevent optical crosstalk between adjacent pixels.

FIG. 11 is a simplified cross section view depicting an alternate fabrication step to the step shown in FIG. 2 in an embodiment in accordance with the invention. A base trench layer (trenches 404-0) is formed in ILD layer 216. Trenches 404-0 bring the optical waveguides closer in proximity to photodetectors 204. A mask layer (not shown) is formed and patterned on ILD layer 216 to form openings where trenches 404-0 are to be formed. The trenches are then etched in ILD layer 216. This step is similar to the step shown in FIG. 4.

In one embodiment in accordance with the invention, trenches 404-0 are etched separately from that of the contacts (not shown) to prevent trenches 404-0 from reaching transfer gates 214 or substrate 202. Trenches 404-0 can be filled with a reflecting material at the same time as the contacts in an embodiment in accordance with the invention. Fabrication of image sensor 200 can now continue with the steps shown in FIGS. 3-10.

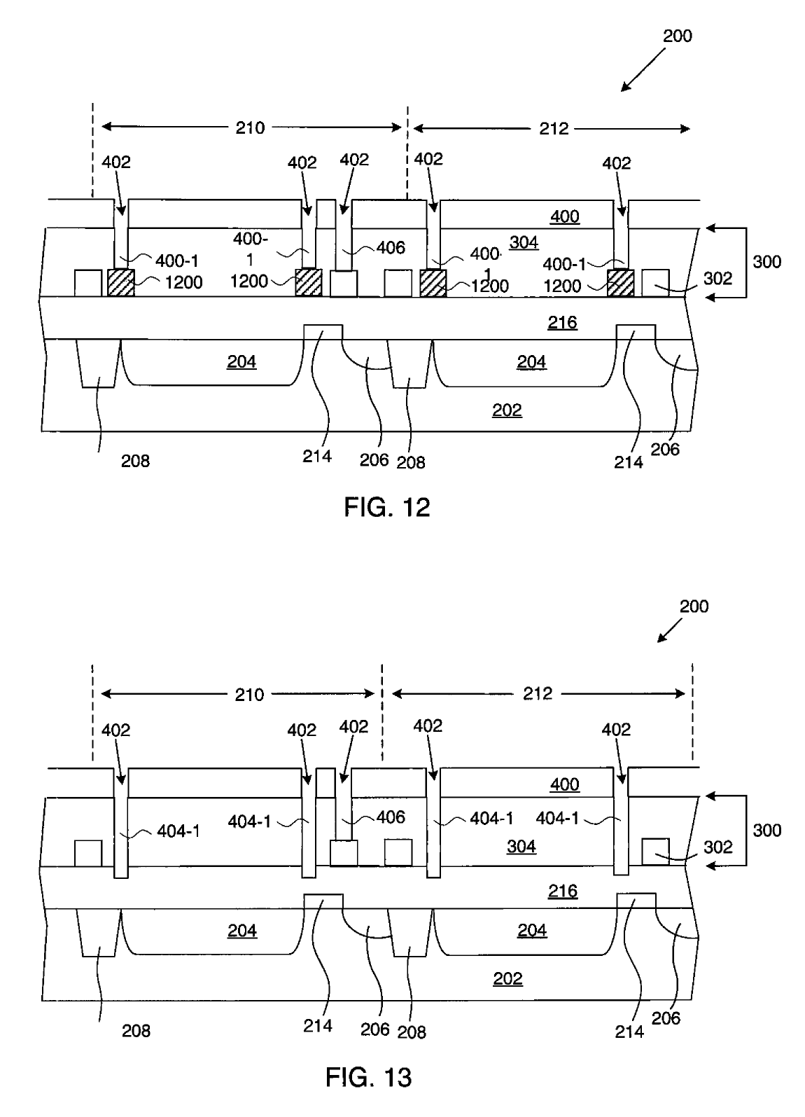

Referring now to FIG. 12, there is shown a simplified cross section view of an alternate fabrication step to the step shown in FIG.4 in an embodiment in accordance with the invention. After the formation of contacts (not shown) to different elements shown in FIG.3, such as, for example, contacts to charge-to-voltage conversion mechanisms 206 or to transfer gates 214, IMD layer 300 is formed over ILD layer 216. IMD layer 300 includes conductive interconnects 302, etch stops 1200, and dielectric layer 304.

IMD layer 300 is formed by first depositing a conductive film over ILD layer 216 and then patterning and etching the conductive film to form conductive interconnects 302 and etch stops 1200. Dielectric layer 304 is then formed over conductive interconnects 302 and ILD layer 216. When trenches 404-1 are formed in dielectric layer 304, etch stops 1200 limit how deep the trenches can be formed in dielectric layer 304. Fabrication of image sensor 200 can now continue with the steps shown in FIGS. 5-10.

FIG. 13 is a cross section view of an alternate fabrication step to the step shown in FIG. 4 in an embodiment in accordance with the invention. Mask layer 400 is deposited and patterned to create openings 402. Trenches 404-1 and vias 406 are then simultaneously formed in dielectric layer 304 in an embodiment in accordance with the invention. In this alternate step, trenches 404-1 are formed through dielectric layer 304 and extend partially into ILD layer 216. Fabrication of image sensor 200 can now continue with the steps shown in FIGS. 5-10.

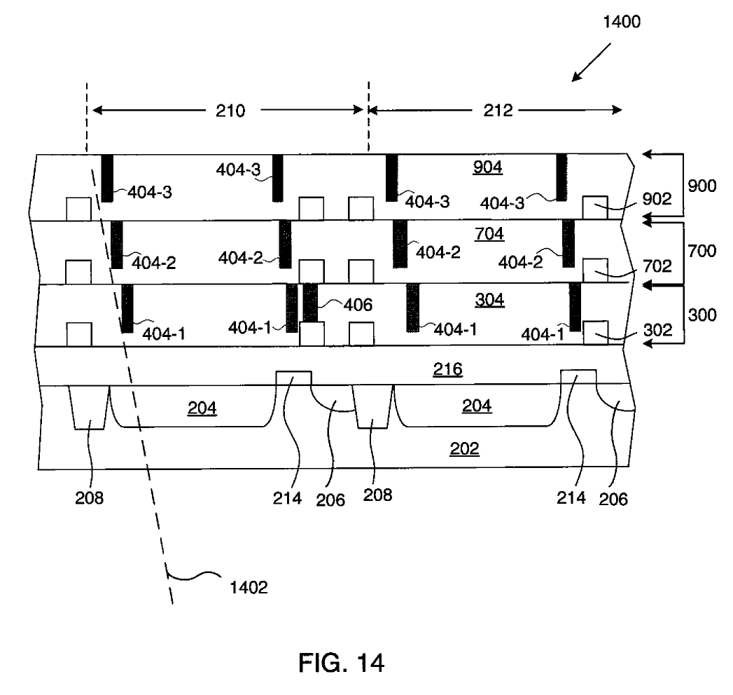

Referring now to FIG. 14, there is shown a simplified cross section view of a first alternate image sensor to the image sensor 200 shown in FIG. 10 in an embodiment in accordance with the invention. In the embodiment of FIG. 10, trenches 404-1, 404-2, 404-3 align and form optical waveguide structures having straight or substantially straight sidewalls. In the embodiment of FIG. 14, trenches 404-1, 404-2, 404-3 in image sensor 1400 do not form optical waveguide structures having straight or substantially straight sidewalls. Instead, trenches 404-1, 404-2, 404-3 are shifted or eased along line 1402.

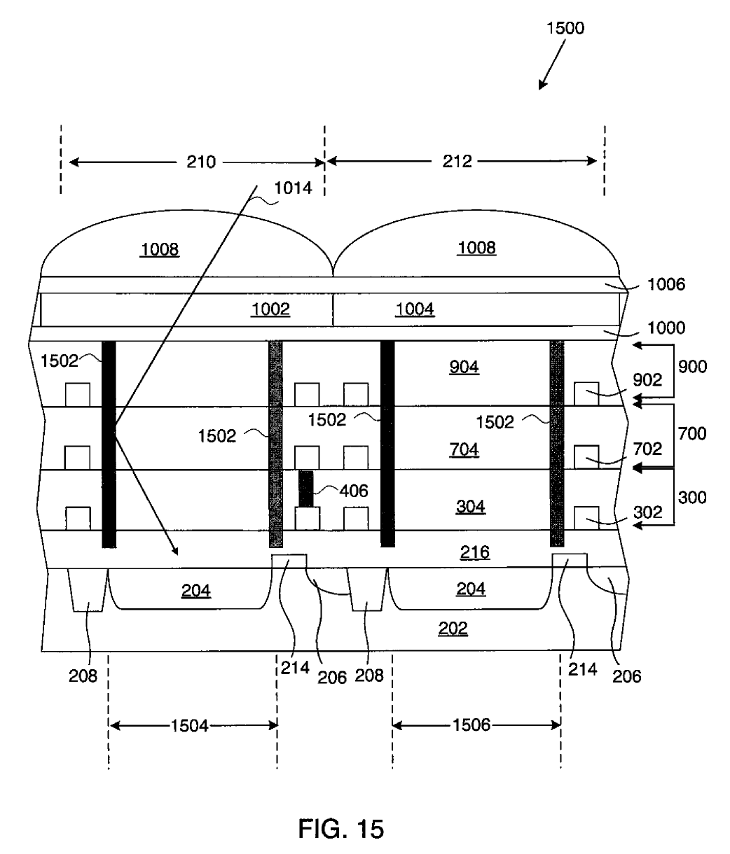

FIG. 15 is a simplified cross section view of a second alternate image sensor to the image sensor 200 shown in FIG. 10 in an embodiment in accordance with the invention. In this embodiment, ILD layer 216 and IMD layers 300, 700, 900 are formed on image sensor 1500. Prior to the formation of passivation layer 1000, multi-level trenches 1502 are formed through IMD layers 300, 700, 900 and into ILD layer 216. A mask layer (not shown) is formed and patterned on the top surface of IMD layer 900. Openings in the mask layer are positioned at the locations of multi-level trenches 1502. Multi-level trenches 1502 are then etched through IMD layers 300, 700, 900 and into ILD layer 216 (similar to the step shown in FIG. 4).

The mask layer is then removed and a reflecting material formed over image sensor 1500 (similar to the step shown in FIG. 5). The reflecting material fills multi-level trenches 1502 and is disposed on a top surface of IMD layer 900. The reflecting material on the surface of IMD layer 900 is then removed from the surface while the reflecting material fills multi-level trenches 1502 (similar to the step shown in FIG. 6).

After the formation of multi-level trenches 1502, passivation layer 1000, color filters 1002, 1004, planar layer 1006, and microlenses 1008 are formed on image sensor 1500. Multi-level trenches 1502 form optical waveguides 1504, 1506. In other embodiments in accordance with the invention, multi-level trenches 1502 are formed through IMD layers 300, 700 and into IMD layer 900 (but not into ILD layer 216).

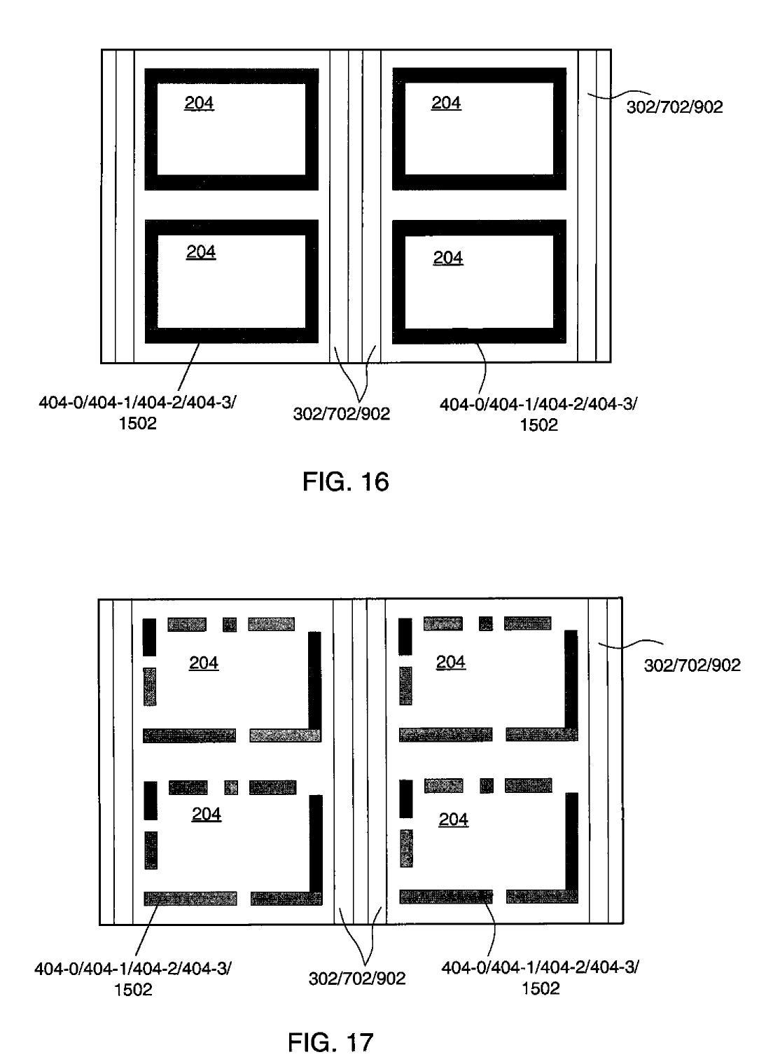

Referring now to FIG. 16, there is shown a top view of an image sensor in a first embodiment in accordance with the invention. Conductive interconnects 302, 702, 902 are disposed between photodetectors 204. Trenches 404-0, 404-1, 404-2, 404-3, or multi-level trenches 1502 are overlaid over one another and completely surround photodetectors 204.

FIG. 17 is a top view of an image sensor in a second embodiment in accordance with the invention. Conductive interconnects 302, 702, 902 are disposed between photodetectors 204. Trenches 404-0, 404-1, 404-2, 404-3, or multi-level trenches 1502 are overlaid over one another and surround photodetectors 204 in non-continuous segments.

The invention has been described in detail with particular reference to certain preferred embodiments thereof, but it will be understood that variations and modifications can be effected within the spirit and scope of the invention. By way of example only, trenches 404-0, 404-1, 404-2, 404-3 are shown as filled completely with the reflecting material. Other embodiments in accordance with the invention can partially fill the trenches with the reflecting material by disposing the reflecting material along the sidewalls of the trenches. Additionally, the present invention has been described and illustrated with respect to a front-illuminated image sensor. Other embodiments in accordance with the invention can implement the optical waveguide structures of the present invention in back-illuminated image sensors.

PARTS LIST

| | |
|---|---|
| 100 | image capture device |
| 102 | light |
| 104 | imaging stage |
| 106 | image sensor |
| 108 | processor |
| 110 | memory |
| 112 | display |
| 114 | other I/O |
| 200 | image sensor |
| 202 | substrate |
| 204 | photodetector |
| 206 | charge-to-voltage conversion mechanism |
| 208 | shallow trench isolation (STI) regions |
| 210 | pixel |
| 212 | pixel |
| 214 | transfer gate |
| 216 | Inter-Level-Dielectric (ILD) layer |
| 300 | Inter-Metal-Dielectric (IMD) layer |
| 302 | conductive interconnects |
| 304 | dielectric layer |
| 400 | mask layer |
| 402 | openings |
| 404-0 | trenches (base trench level) |
| 404-1 | trenches (first trench level) |
| 404-2 | trenches (second trench level) |
| 404-3 | trenches (third trench level) |
| 406 | via |
| 500 | reflecting material |
| 502 | surface |
| 700 | IMD layer |
| 702 | conductive interconnects |
| 704 | dielectric layer |
| 900 | IMD layer |
| 902 | conductive interconnects |
| 904 | dielectric layer |
| 1000 | passivation layer |
| 1002 | color filter |
| 1004 | color filter |
| 1006 | planar layer |
| 1008 | microlens |
| 1010 | optical waveguide |
| 1012 | optical waveguide |
| 1014 | light |
| 1200 | etch stop |
| 1400 | image sensor |
| 1402 | dashed line |
| 1500 | image sensor |
| 1502 | multi-level trenches |
| 1504 | optical waveguide |
| 1506 | optical waveguide |

1. A method for fabricating a plurality of optical waveguides in an image sensor, wherein the image sensor includes a substrate having a plurality of photodetectors formed therein that form an imaging area, the method comprising the steps of:
forming a dielectric layer over the imaging area;
etching a plurality of trenches in at least a portion of the dielectric layer, wherein subsets of the plurality of trenches are disposed around the edges of each photodetector; and
at least partially filling each trench with a reflecting material.

2. The method of claim 1, wherein the step of etching a plurality of trenches in at least a portion of the dielectric layer, wherein subsets of the plurality of trenches are disposed around the edges of each photodetector comprises etching a plurality of trenches in a portion of the dielectric layer, wherein subsets of the plurality of trenches are disposed around the edges of each photodetector.

3. The method of claim 2, further comprising repeating the steps of:
forming another dielectric layer over the imaging area; and
etching a plurality of trenches in a portion of the other dielectric layer, wherein subsets of the plurality of trenches are disposed around the edges of each photodetector; and
at least partially filling each trench with a reflecting material.

4. The method of claim 3, wherein the step of etching a plurality of trenches in at least a portion of the dielectric layers comprises:
forming a mask layer over the imaging area, and patterning the mask layer to form openings in the mask layer that correspond to the locations of the plurality of trenches;
etching the plurality of trenches in at least a portion of the dielectric layer through the openings in the mask layer; and
removing the mask layer.

5. The method of claim 4, wherein the step of forming a mask layer over the imaging area, and patterning the mask layer to form openings in the mask layer that correspond to the locations of the plurality of trenches comprises the step of forming a mask layer over the imaging area, and patterning the mask layer to form openings in the mask layer that correspond to the locations of the plurality of trenches and one or more vias.

6. The method of claim 5, further comprising the step of etching the one or more vias in the dielectric layer through at the same time the plurality of trenches are etched in the dielectric layer.

7. The method of claim 6, further comprising the step of filling each via with the reflecting material at the same time the plurality of trenches are at least partially filled with the reflecting material.

8. The method of claim 1, wherein the step of etching a plurality of trenches in at least a portion of the dielectric layer comprises the step of etching a plurality of trenches through the dielectric layer.

9. The method of claim 8, further comprising the step of etching the plurality of trenches into an underlying dielectric layer.

10. The method of claim 1, further comprising the step of forming a plurality of etch stops prior to forming a dielectric layer over the imaging area, wherein each etch stop is formed at a location that corresponds to a locations of a respective one of the plurality of trenches.

11. The method of claim 3, wherein the locations of the plurality of trenches formed in one dielectric layer is laterally shifted a given distance from the locations of the plurality of trenches formed in another dielectric layer.

12. The method of claim 1, wherein the step of at least partially filling each trench with a reflecting material comprises at least partially filling each trench with a metal.

13. A method for fabricating a plurality of optical waveguides in an image sensor, wherein the image sensor includes a substrate having a plurality of photosensitive areas formed therein that form an imaging area, the method comprising the steps of:
forming a first dielectric layer over the imaging area and a second dielectric layer over the first dielectric layer;
etching a plurality of trenches through the second dielectric layer and into at least a portion of the first dielectric layer, wherein subsets of the plurality of trenches are disposed around the edges of each photosensitive area; and
at least partially filling each trench with a reflecting material.

14. The method of claim 13, further comprising the step of forming a third dielectric layer over the second dielectric layer prior to performing the step of etching the plurality of trenches.

15. The method of claim 14, wherein the step of etching a plurality of trenches through the second dielectric layer and into at least a portion of the first dielectric layer, wherein subsets of the plurality of trenches are disposed around the edges of each photosensitive area comprises etching a plurality of trenches through the third and second dielectric layers and into at least a portion of the first dielectric layer, wherein subsets of the plurality of trenches are disposed around the edges of each photosensitive area.

16. The method of claim 15, wherein the step of etching a plurality of trenches through the third and second dielectric layers and into at least a portion of the first dielectric layer comprises:
forming a mask layer over the third dielectric layer and patterning the mask layer to form openings in the mask layer that correspond to the locations of the plurality of trenches;
etching the plurality of trenches through the third and second dielectric layers and into at least a portion of the first dielectric layer through the openings in the mask layer; and
removing the mask layer.

17. The method of claim 13, further comprising the step of forming a plurality of etch stops prior to forming a first dielectric layer over the imaging area and a second dielectric layer over the first dielectric layer.

18. The method of claim 13, wherein the step of at least partially filling each trench with a reflecting material comprises at least partially filling each trench with a metal.
